(19) United States
(12) Patent Application Publication
(10) Pub. No.: US 2016/0077166 A1
(43) Pub. Date: Mar. 17, 2016

(54) SYSTEMS AND METHODS FOR ORIENTATION PREDICTION

(71) Applicant: InvenSense, Incorporated, San Jose, CA (US)

(72) Inventors: Alexey Morozov, Sunnyvale, CA (US); Shang-Hung Lin, San Jose, CA (US); Sinan Karahan, Menlo Park, CA (US)

(21) Appl. No.: 14/485,248

(22) Filed: Sep. 12, 2014

(51) Int. Cl. G01R 33/028; G01P 15/00; G01C 19/00

(52) U.S. Cl. CPC G01R 33/0286; G01C 19/00; G01P 15/00

(57) ABSTRACT

Systems and methods are disclosed for predicting a future orientation of a device. A future motion sensor sample may be predicted using a plurality of motion sensor samples for the device up to a current time. After determining the current orientation of the device, the predicted motion sensor sample may be used to predict a future orientation of the device at one or more times.

### FIELD OF THE PRESENT DISCLOSURE

This disclosure generally relates to utilizing motion sensor data from a device that is moved by a user and more specifically to predicting a future orientation of the device.

### BACKGROUND

A wide variety of motion sensors are now being incorporated into mobile devices, such as cell phones, laptops, tablets, gaming devices and other portable, electronic devices. Often, such sensors rely on microelectromechanical systems (MEMS) techniques, although other technologies may also be used. Non-limiting examples of motion sensors include an accelerometer, a gyroscope, a magnetometer, and the like. Further, sensor fusion processing may be performed to combine the data from a plurality of different types of sensors to provide an improved characterization of the device's motion or orientation.

In turn, numerous applications have been developed to utilize the availability of such sensor data. For example, the device may include a display used to depict a virtual three dimensional environment such that the image displayed is responsive to a determined orientation of the device. In one aspect, such a device may be a head-mounted display that tracks motion of a user's head in order to update the display of the virtual environment, although the device may also be secured to a different part of the user or may be moved by hand. As will be appreciated, the virtual environment may be completely synthetic or may be reality-based, potentially with additional information displayed as an overlay.

Currently available technologies used to compute a virtual scene may take longer than the sensor sampling period, such as 0.02 s for a sensor system operating at 50 Hz. Accordingly, if only the current orientation is known, the image on the display may lag behind the true orientation and may cause the user to get discomforted or even nauseated. It would be desirable to accurately predict a future orientation of the device to allow the depiction of the virtual environment to be rendered ahead of time to reduce lag. This disclosure provides systems and methods for achieving this and other goals as described in the following materials.

### SUMMARY

As will be described in detail below, this disclosure relates to methods for predicting a future orientation of a device configured to be moved by a user, including obtaining a plurality of motion sensor samples for the device up to a current time, generating a quaternion representing a current orientation of the device, predicting a future motion sensor sample, based at least in part, on the plurality of motion samples obtained up to the current time and generating a quaternion representing a predicted future orientation of the device by fusing the predicted future motion sensor sample with the current orientation quaternion.

In one aspect, a plurality of future motion sensor samples may be predicted, wherein each motion sensor sample represents a successive future time and a plurality of quaternions representing predicted future orientations of the device may be generated, wherein each generated quaternion is derived by fusing one of the plurality of motion sensor samples with a preceding orientation quaternion. Further, a future motion sensor sample may be predicted for data from at least one of the group consisting of a gyroscope, an accelerometer and a magnetometer.

In one aspect, predicting a future motion sensor sample may include deriving a linear function from the plurality of motion sensor samples. In another aspect, predicting a future motion sensor sample may include deriving a nonlinear function from the plurality of motion sensor samples.

In one aspect, predicting a future motion sensor sample may include providing a frequency domain representation of a differential equation corresponding to typical motion of the device receiving as inputs the plurality of motion sensor samples. The differential equation may be trained with respect to the typical motion.

In one aspect, predicting a future motion sensor sample may include providing an artificial neural network representing typical motion of the device receiving as inputs the plurality of motion sensor samples. The artificial neural network may be trained with respect to the typical motion.

In yet another aspect, predicting a future motion sensor sample may include combining a plurality of predictions obtained from the group consisting of deriving a linear function from the plurality of motion sensor samples, deriving a nonlinear function from the plurality of motion sensor samples, providing a frequency domain representation of a differential equation corresponding to typical motion of the device receiving as inputs the plurality of motion sensor samples and providing an artificial neural network representing typical motion of the device receiving as inputs the plurality of motion sensor samples.

Generating the quaternion representing a predicted future orientation of the device may include integrating the predicted future motion sensor sample with the current orientation quaternion.

In one aspect, a graphical representation of a virtual environment may be generated using the predicted future orientation quaternion. The device may be configured to track the motion of the user's head.

This disclosure is also directed to systems for predicting orientation. Such systems may include a device configured to be moved by a user outputting motion sensor data, a data prediction block configured to receive a plurality of samples of the motion sensor data up to a current time and output a predicted future motion sensor sample, a quaternion generator configured to output a quaternion representing a current orientation of the device and a sensor fusion block configured to generate a quaternion representing a predicted future orientation of the device by combining the predicted future motion sensor sample with the current orientation quaternion.

In one aspect, the sensor predictor may output a plurality of predicted future motion sensor samples, wherein each motion sensor sample represents a successive future time such that the sensor fusion block may generate a plurality of quaternions representing predicted future orientations of the device each derived by combining one of the plurality of motion sensor samples with a preceding orientation quaternion. Further, the data prediction block may predict data from at least one of the group consisting of a gyroscope, an accelerometer and a magnetometer.

In one aspect, the data prediction block may output the predicted future motion sensor sample by deriving a linear function from the plurality of motion sensor samples. In another aspect, the data prediction block may output the predicted future motion sensor sample by deriving a nonlinear function from the plurality of motion sensor samples.

In one aspect, the data prediction block may be a frequency domain representation of a differential equation corresponding to typical motion of the device receiving as inputs the plurality of motion sensor samples. In another aspect, the data prediction block may be an artificial neural network representing typical motion of the device receiving as inputs the plurality of motion sensor samples.

In one aspect, the sensor fusion block may generate the quaternion representing a predicted future orientation of the device by integrating the predicted future motion sensor sample with the current orientation quaternion.

According to the disclosure, the system may also include an image generator to render a graphical representation of a virtual environment using the predicted future orientation quaternion. The device may track the motion of the user's head. Further, the system may include a display to output the rendered graphical representation.

### BRIEF DESCRIPTION OF THE DRAWINGS

FIG. 1 is a schematic diagram of a device for predicting a future orientation according to an embodiment.

FIG. 2 is a schematic diagram of an orientation predictor according to an embodiment.

FIG. 3 is a schematic diagram of a data prediction block employing a linear function according to an embodiment.

FIG. 4 is a schematic diagram of a data prediction block employing a nonlinear function according to an embodiment.

FIG. 5 is a schematic diagram of a data prediction block employing a dynamic system according to an embodiment.

FIG. 6 is a schematic diagram of a pole-zero plot of a difference equation according to an embodiment.

FIG. 7 is a schematic diagram of a pole-zero plot of a difference equation according to another embodiment.

FIG. 8 is a schematic diagram of a data prediction block employing an artificial neural network according to an embodiment.

FIG. 9 is a schematic diagram of a data prediction block employing an artificial neural network according to another embodiment.

FIG. 10 is a schematic diagram of a head mounted display for predicting a future orientation according to an embodiment

FIG. 11 is a flowchart showing a routine for predicting a future orientation of a device according to an embodiment.

### DETAILED DESCRIPTION

At the outset, it is to be understood that this disclosure is not limited to particularly exemplified materials, architectures, routines, methods or structures as such may vary. Thus, although a number of such options, similar or equivalent to those described herein, can be used in the practice or embodiments of this disclosure, the preferred materials and methods are described herein.

It is also to be understood that the terminology used herein is for the purpose of describing particular embodiments of this disclosure only and is not intended to be limiting.

The detailed description set forth below in connection with the appended drawings is intended as a description of exemplary embodiments of the present disclosure and is not intended to represent the only exemplary embodiments in which the present disclosure can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the specification. It will be apparent to those skilled in the art that the exemplary embodiments of the specification may be practiced without these specific details. In some instances, well known structures and devices are shown in block diagram form in order to avoid obscuring the novelty of the exemplary embodiments presented herein.

For purposes of convenience and clarity only, directional terms, such as top, bottom, left, right, up, down, over, above, below, beneath, rear, back, and front, may be used with respect to the accompanying drawings or chip embodiments. These and similar directional terms should not be construed to limit the scope of the disclosure in any manner.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the exemplary wireless communications devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, performs one or more of the methods described above. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor. For example, a carrier wave may be employed to carry computer-readable electronic data such as those used in transmitting and receiving electronic mail or in accessing a network such as the Internet or a local area network (LAN). Of course, many modifications may be made to this configuration without departing from the scope or spirit of the claimed subject matter.

The various illustrative logical blocks, modules, circuits and instructions described in connection with the embodiments disclosed herein may be executed by one or more processors, such as one or more motion processing units (MPUs), digital signal processors (DSPs), general purpose microprocessors, application specific integrated circuits (ASICs), application specific instruction set processors (ASIPs), field programmable gate arrays (FPGAs), or other equivalent integrated or discrete logic circuitry. The term “processor,” as used herein may refer to any of the foregoing structure or any other structure suitable for implementation of the techniques described herein. In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any conventional processor, controller, microcontroller, or state machine. A processor may also be implemented as a combination of computing devices, e.g., a combination of an MPU and a microprocessor, a plurality of microprocessors, one or more microprocessors in conjunction with an MPU core, or any other such configuration.

Unless defined otherwise, all technical and scientific terms used herein have the same meaning as commonly understood by one having ordinary skill in the art to which the disclosure pertains.

Finally, as used in this specification and the appended claims, the singular forms “a, “an” and “the” include plural referents unless the content clearly dictates otherwise.

In the described embodiments, a chip is defined to include at least one substrate typically formed from a semiconductor material. A single chip may be formed from multiple substrates, where the substrates are mechanically bonded to preserve the functionality. A multiple chip includes at least two substrates, wherein the two substrates are electrically connected, but do not require mechanical bonding. A package provides electrical connection between the bond pads on the chip to a metal lead that can be soldered to a PCB. A package typically comprises a substrate and a cover. Integrated Circuit (IC) substrate may refer to a silicon substrate with electrical circuits, typically CMOS circuits. MEMS cap provides mechanical support for the MEMS structure. The MEMS structural layer is attached to the MEMS cap. The MEMS cap is also referred to as handle substrate or handle wafer. In the described embodiments, an electronic device incorporating a sensor may employ a motion tracking module also referred to as Motion Processing Unit (MPU) that includes at least one sensor in addition to electronic circuits. The sensor, such as a gyroscope, a compass, a magnetometer, an accelerometer, a microphone, a pressure sensor, a proximity sensor, or an ambient light sensor, among others known in the art, are contemplated. Some embodiments include accelerometer, gyroscope, and magnetometer, which each provide a measurement along three axes that are orthogonal relative to each other referred to as a 9-axis device. Other embodiments may not include all the sensors or may provide measurements along one or more axes. The sensors may be formed on a first substrate. Other embodiments may include solid-state sensors or any other type of sensors. The electronic circuits in the MPU receive measurement outputs from the one or more sensors. In some embodiments, the electronic circuits process the sensor data. The electronic circuits may be implemented on a second silicon substrate. In some embodiments, the first substrate may be vertically stacked, attached and electrically connected to the second substrate in a single semiconductor chip, while in other embodiments the first substrate may be disposed laterally and electrically connected to the second substrate in a single semiconductor package.

In one embodiment, the first substrate is attached to the second substrate through wafer bonding, as described in commonly owned U.S. Pat. No. 7,104,129, which is incorporated herein by reference in its entirety, to simultaneously provide electrical connections and hermetically seal the MEMS devices. This fabrication technique advantageously enables technology that allows for the design and manufacture of high performance, multi-axis, inertial sensors in a very small and economical package. Integration at the wafer-level minimizes parasitic capacitances, allowing for improved signal-to-noise relative to a discrete solution. Such integration at the wafer-level also enables the incorporation of a rich feature set which minimizes the need for external amplification.

In the described embodiments, raw data refers to measurement outputs from the sensors which are not yet processed. Depending on the context, motion data may refer to processed raw data, which may involve applying a sensor fusion algorithm or applying any other algorithm. In the case of a sensor fusion algorithm, data from one or more sensors may be combined to provide an orientation of the device. In the described embodiments, an MPU may include processors, memory, control logic and sensors among structures.

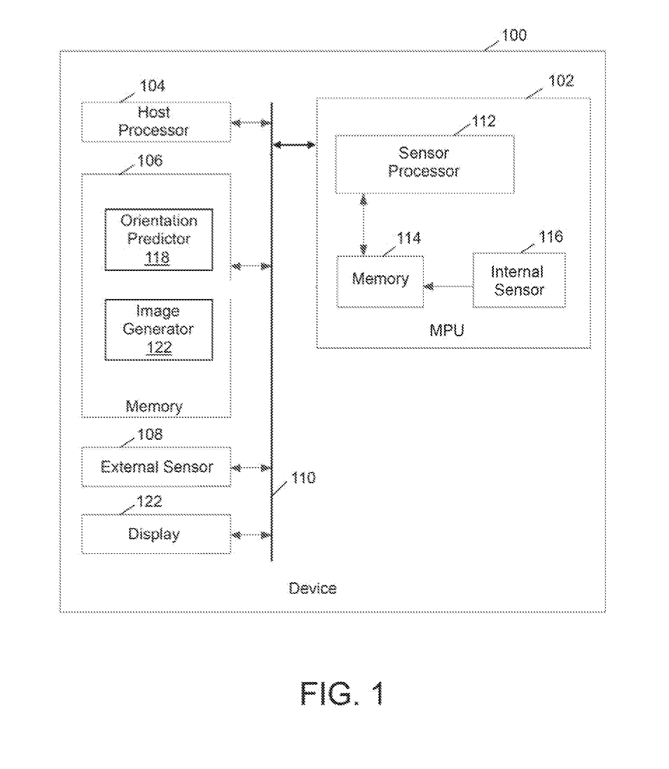

Details regarding one embodiment of a mobile electronic device 100 including features of this disclosure are depicted as high level schematic blocks in FIG. 1. As will be appreciated, device 100 may be implemented as a device or apparatus, such as a handheld device or a device that is secured to a user that can be moved in space by the user and its motion and/or orientation in space therefore sensed. In one embodiment, device 100 may be configured as a head-mounted display as discussed in further detail below. However, the device may also be a mobile phone (e.g., cellular phone, a phone running on a local network, or any other telephone handset), tablet, laptop, personal digital assistant (PDA), video game player, video game controller, navigation device, mobile internet device (MID), personal navigation device (PND), digital still camera, digital video camera, binoculars, telephoto lens, portable music, video, or media player, remote control, or other handheld device, or a combination of one or more of these devices.

In some embodiments, device 100 may be a self-contained device that includes its own display, sensors and processing as described below. However, in other embodiments, the functionality of device 100 may be implemented with one or more portable or non-portable devices that, in addition to the non-limiting examples of portable device may include a desktop computer, electronic tabletop device, server computer, etc. which can communicate with each, e.g., via network connections. In general, a system within the scope of this disclosure may include at least one mobile component incorporating sensors used to determine orientation and processing resources to receive data from the motion sensors to determine orientation that may be integrated with the sensor component or may be separate. In further aspects, the system may also include a display for depicting a virtual environment by providing a view that is responsive to the determined orientation. Additionally, the display may be integrated with the sensor component or may be external and stationary or mobile. The system may further include processing resources to generate the scenes to be viewed on the display based, at least in part, on the determined orientation. The components of the system may be capable of communicating via a wired connection using any type of wire-based communication protocol (e.g., serial transmissions, parallel transmissions, packet-based data communications), wireless connection (e.g., electromagnetic radiation, infrared radiation or other wireless technology), or a combination of one or more wired connections and one or more wireless connections. The processing resources may be integrated with the sensor component, the display, and/or additional components and may be allocated in any desired distribution.

As shown, device 100 includes MPU 102, host processor 104, host memory 106, and external sensor 108. Host processor 104 may be configured to perform the various computations and operations involved with the general function of device 100, and may also perform any or all of the functions associated with orientation prediction according to this disclosure as desired. Host processor 104 is shown coupled to MPU 102 through bus 110, which may be any suitable bus or interface, such as a peripheral component interconnect express (PCIe) bus, a universal serial bus (USB), a universal asynchronous receiver/transmitter (UART) serial bus, a suitable advanced microcontroller bus architecture (AMBA) interface, an Inter-Integrated Circuit (I2C) bus, a serial digital input output (SDIO) bus, or other equivalent. Host memory 106 may include programs, drivers or other data that utilize information provided by MPU 102. Exemplary details regarding suitable configurations of host processor 104 and MPU 102 may be found in co-pending, commonly owned U.S. patent application Ser. No. 12/106,921, filed Apr. 21, 2008, which is hereby incorporated by reference in its entirety.

In this embodiment, MPU 102 is shown to include sensor processor 112, memory 114 and internal sensor 116. Memory 114 may store algorithms, routines or other instructions for processing data output by sensor 116 or sensor 108 as well as raw data and motion data. Internal sensor 116 may include one or more sensors, including motion sensors such as accelerometers, gyroscopes and magnetometers and/or other sensors. Likewise, depending on the desired configuration, external sensor 108 may include one or more motion sensors or other sensors, such as pressure sensors, microphones, proximity, and ambient light sensors, and temperature sensors. As used herein, an internal sensor refers to a sensor implemented using the MEMS techniques described above for integration with an MPU into a single chip. Similarly, an external sensor as used herein refers to a sensor carried on-board the device that is not integrated into an MPU.

In some embodiments, the sensor processor 112 and internal sensor 116 are formed on different chips and in other embodiments; they reside on the same chip. In yet other embodiments, a sensor fusion algorithm that is employed in calculating orientation of device is performed externally to the sensor processor 112 and MPU 102, such as by host processor 104. In still other embodiments, the sensor fusion is performed by MPU 102. More generally, device 100 incorporates MPU 102 as well as host processor 104 and host memory 106 in this embodiment.

As will be appreciated, host processor 104 and/or sensor processor 112 may be one or more microprocessors, central processing units (CPUs), or other processors which run software programs for device 100 or for other applications related to the functionality of device 100, including the orientation prediction techniques of this disclosure. In addition, host processor 104 and/or sensor processor 112 may execute instructions associated with different software application programs such as menu navigation software, games, camera function control, navigation software, and phone or a wide variety of other software and functional interfaces can be provided. In some embodiments, multiple different applications can be provided on a single device 100, and in some of those embodiments, multiple applications can run simultaneously on the device 100. In some embodiments, host processor 104 implements multiple different operating modes on device 100, each mode allowing a different set of applications to be used on the device and a different set of activities to be classified. As used herein, unless otherwise specifically stated, a “set” of items means one item, or any combination of two or more of the items.

Multiple layers of software can be provided on a computer readable medium such as electronic memory or other storage medium such as hard disk, optical disk, flash drive, etc., for use with host processor 104 and sensor processor 112. For example, an operating system layer can be provided for device 100 to control and manage system resources in real time, enable functions of application software and other layers, and interface application programs with other software and functions of device 100. A motion algorithm layer can provide motion algorithms that provide lower-level processing for raw sensor data provided from the motion sensors and other sensors, such as internal sensor 116 and/or external sensor 108. Further, a sensor device driver layer may provide a software interface to the hardware sensors of device 100.

Some or all of these layers can be provided in host memory 106 for access by host processor 104, in memory 114 for access by sensor processor 112, or in any other suitable architecture. For example, in some embodiments, host processor 104 may implement orientation predictor 118, representing a set of processor-executable instructions stored in memory 106, for using sensor inputs, such as sensor data from internal sensor 116 as received from MPU 102 and/or external sensor 108 to predict an orientation of device 100 at a future time. In other embodiments, as will be described below, other divisions of processing may be apportioned between the sensor processor 112 and host processor 104 as is appropriate for the applications and/or hardware used, where some of the layers (such as lower level software layers) are provided in MPU 102. Further, host memory 106 is also shown to include image generator 120, representing a set of processor-executable instructions to render a graphical representation of a virtual, three dimensional environment that is responsive to a determined orientation of device 100. According to the techniques of this disclosure, the determined orientation may be based, at least in part, on one or more anticipated future orientations output by orientation predictor 118. Image generator 120 may output the rendered scene on display 122.

A system that utilizes orientation predictor 118 in accordance with the present disclosure may take the form of an entirely hardware implementation, an entirely software implementation, or an implementation containing both hardware and software elements. In one implementation, orientation predictor 118 is implemented in software, which includes, but is not limited to, application software, firmware, resident software, microcode, etc. Furthermore, orientation predictor 118 may take the form of a computer program product accessible from a computer-usable or computer-readable medium providing program code for use by or in connection with a computer or any instruction execution system. For the purposes of this description, a computer-usable or computer-readable medium may be any apparatus that can contain, store, communicate, propagate, or transport the program for use by or in connection with the instruction execution system, apparatus, or device.

According to the details below, orientation predictor 118 may receive raw motion sensor data from external sensor 108 and/or internal sensor 116 and also receive a determined current orientation of device 100, such may be determined by sensor processor 112 and output by MPU 102. In one embodiment, sensor processor 112 may generate a quaternion. In other embodiments, similar functionality may be provided by host processor 104. For example, the orientation of device 100 may be represented by a rotation operation that would align the body frame of device 100 with a stationary frame of reference that is independent of the body frame, such as a “world frame.” In some embodiments, determination of the orientation of device 100 in reference to the world frame may be performed by detecting external fields, such as Earth's gravity using an accelerometer and/or Earth's magnetic field using a magnetometer. Other suitable reference frames that are independent of the body frame may be used as desired. In the embodiments described below, the rotation operation may be expressed in the form of a unit quaternion Q̅. As used herein, the terms “quaternion” and “unit quaternion” may used interchangeably for convenience. Accordingly, a quaternion may be a four element vector describing the transition from one rotational orientation to another rotational orientation and may be used to represent the orientation of device 100 with respect to the reference frame. A unit quaternion has a scalar term and 3 imaginary terms. Thus, a rotation operation representing the attitude of device 100 may be described as a rotation of angle θ about the unit vector [uₓ, u_{y}, u_{z}] as indicated by Equation 1.

$$\overline{Q} = [ \begin{matrix}cos ( \frac{θ}{2} ) \\ sin ( \frac{θ}{2} ) \cdot {u}_{x} \\ sin ( \frac{θ}{2} ) \cdot {u}_{y} \\ sin ( \frac{θ}{2} ) \cdot {u}_{z}\end{matrix} ] \qquad ( 1 )$$

In other embodiments, the rotation operation may be expressed in any other suitable manner. For example, a rotation matrix employing Euler angles may be used to represent sequential rotations with respect to fixed orthogonal axes, such as rotations in the yaw, pitch and roll directions. As such, the operations described below may be modified as appropriate to utilize rotation matrices if desired.

Raw data output by a motion sensor, such as external sensor 108 and/or internal sensor 116, may be in the form of a component for each orthogonal axis of the body frame. For example, raw gyroscope output may be represented as Gₓ, G_{y} and G_{z}. Conversion of this data to gyroscope in the world frame, G_{wx}, G_{wy} and G_{wz} may be performed readily using quaternion multiplication and inversion. For quaternions

$$\overline{{Q}_{1}} = [ \begin{matrix}{q}_{1 w} \\ {q}_{1 x} \\ {q}_{1 y} \\ {q}_{1 z}\end{matrix} ] and \overline{{Q}_{2}} = [ \begin{matrix}{q}_{2 w} \\ {q}_{2 x} \\ {q}_{2 y} \\ {q}_{2 z}\end{matrix} ] ,$$

quaternion multiplication may be designated using the symbol “ [symbol] ” and defined as shown in Equation 2 while quaternion inversion may be designated using the symbol “′” and defined as shown in Equation 3.

$$\begin{matrix}\overline{{Q}_{1}} ⊗ \overline{{Q}_{2}} = [ \begin{matrix}{q}_{1 w} \cdot {q}_{2 w} - {q}_{1 x} \cdot {q}_{2 x} - {q}_{1 y} \cdot {q}_{2 y} - {q}_{1 z} \cdot {q}_{2 z} \\ {q}_{1 w} \cdot {q}_{2 x} + {q}_{1 x} \cdot {q}_{2 w} + {q}_{1 y} \cdot {q}_{2 z} - {q}_{1 z} \cdot {q}_{2 y} \\ {q}_{1 w} \cdot {q}_{2 y} - {q}_{1 x} \cdot {q}_{2 z} + {q}_{1 y} \cdot {q}_{2 w} + {q}_{1 z} \cdot {q}_{2 x} \\ {q}_{1 w} \cdot {q}_{2 z} + {q}_{1 x} \cdot {q}_{2 y} - {q}_{1 y} \cdot {q}_{2 x} + {q}_{1 z} \cdot {q}_{2 w}\end{matrix} ] & ( 2 ) \\ \overline{{Q}_{1}^{′}} = [ \begin{matrix}{q}_{1 w} \\ - {q}_{1 x} \\ - {q}_{1 y} \\ - {q}_{1 z}\end{matrix} ] & ( 3 )\end{matrix}$$

As noted above, the orientation Q̅_̅{̅N̅+̅1̅}̅ of device 100 may be determined from simply integrating the gyroscope signal or a sensor fusion operation, such as a 6-axis sensor fusion involving data from a gyroscope and an accelerometer or a 9-axis sensor fusion that also includes data from a magnetometer. Thus, conversion of gyroscope data from the body frame to the world frame may be expressed as Equation 4.

$$\overline{{Q}_{Gw}} = [ \begin{matrix}0 \\ Gwx \\ Gwy \\ Gwz\end{matrix} ] = \overline{{Q}_{N + 1}} ⊗ [ \begin{matrix}0 \\ Gx \\ Gy \\ Gz\end{matrix} ] ⊗ \overline{{Q}_{N + 1}^{′}} \qquad ( 4 )$$

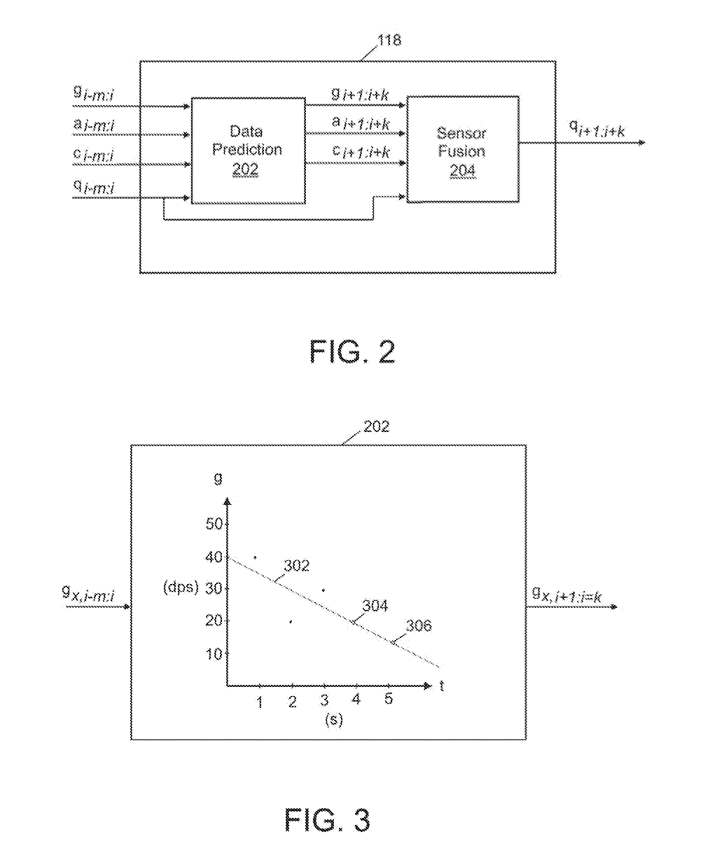

One embodiment of orientation predictor 118 is shown schematically in FIG. 2. Inputs in the form of gyroscope (g), accelerometer (a) and compass (c) are provided to data prediction block 202 from m previous time steps leading to current time step i, such as from external sensor 108 and/or internal sensor 116. Likewise, data prediction block 202 may also receive determined quaternions (q) representing the orientation of device 100 from m previous time steps leading to current time step i, such as from MPU 102. As will be described below, data prediction block 202 may predict one or more of gyroscope, accelerometer, and compass signals at immediate next time step i+1 up to k steps into the future i+k. The predicted motion sensor signals are then fed to sensor fusion block 204 along with the current and previously determined quaternions to generate predicted quaternions representing the anticipated orientation of device 100 at immediate next time step i+1 up to k steps into the future (e.g., qᵢ₊₂, qᵢ₊₃, and so on). Thus, orientations for device 100 may be predicted based on predicted data for any or all of the gyroscope, accelerometer and magnetometer.

The following materials describe exemplary techniques for predicting motion sensor data to be used by sensor fusion block 204. Any or all of the techniques may be employed as desired and one of skill in the art will recognize that other suitable procedures for predicting motion sensor data may also be employed.

In one aspect, data prediction block 202 may be configured to fit a linear function to current and past sensor data. For clarity, the following discussion is in the context of gyroscope data alone, but the techniques may be applied to any combination of motion sensor data from a gyroscope, an accelerometer, a magnetometer or others. A block diagram showing a linear prediction is schematically depicted in FIG. 3. Data prediction block 202 receives input in the form of current and past gyroscope data g_{x,i-m:i} for the body X axis of device 100. Data prediction block 202 may fit linear function 302 to the past data represented by solid dots to allow for prediction of future data 304 and 306. For clarity, only the signal for the X axis is shown, but the other orthogonal axes may be predicted separately in a similar manner or together by replacing the fitted line with a fitted hyper plane or other suitable linear function of three variables.

In the example shown, three past and current gyroscope signals [40 20 30] in degrees per second (dps) were sampled at times [1 2 3] s. A linear function taking the form of Equation 5, wherein g is gyroscope, t is time, m is the slope and b is the intercept may be generated.

g=m*t+b (5)

One suitable technique for fitting a linear function may include performing a least squares algorithm in A X=B form, wherein A is a matrix, X and B are vectors and A and B are data inputs to solve for X, resulting in Equation 6.

$$[ \begin{matrix}{t}_{1} & 1 \\ {t}_{2} & 1 \\ {t}_{3} & 1\end{matrix} ] [ \begin{matrix}m \\ b\end{matrix} ] = [ \begin{matrix}{g}_{3} \\ {g}_{1} \\ {g}_{2}\end{matrix} ] \qquad ( 6 )$$

By substituting the values from the example shown in FIG. 3, Equation 7 may be obtained.

$$[ \begin{matrix}1 & 1 \\ 2 & 1 \\ 3 & 1\end{matrix} ] [ \begin{matrix}m \\ b\end{matrix} ] = [ \begin{matrix}40 \\ 20 \\ 30\end{matrix} ] \qquad ( 7 )$$

An estimate of X may be obtained by multiplying the pseudoinverse of A, A⁺, by B to provide the solution indicated by Equation 8.

$$X = {A}^{+} B = [ \begin{matrix}- 0.5 & 0 & 0.5 \\ 1.3 & 0.3 & - 0.7\end{matrix} ] [ \begin{matrix}40 \\ 20 \\ 30\end{matrix} ] = [ \begin{matrix}- 5 \\ 40\end{matrix} ] \qquad ( 8 )$$

Accordingly, the predicted gyroscope signal for the X axis at time 4 s 304 may be predicted to be 20 dps and at time 5 s 306 may be predicted to be 15 dps. Other linear fitting techniques may be applied as desired. For example, a recursive least squares algorithm which updates parameter estimates for each data sample may be used.

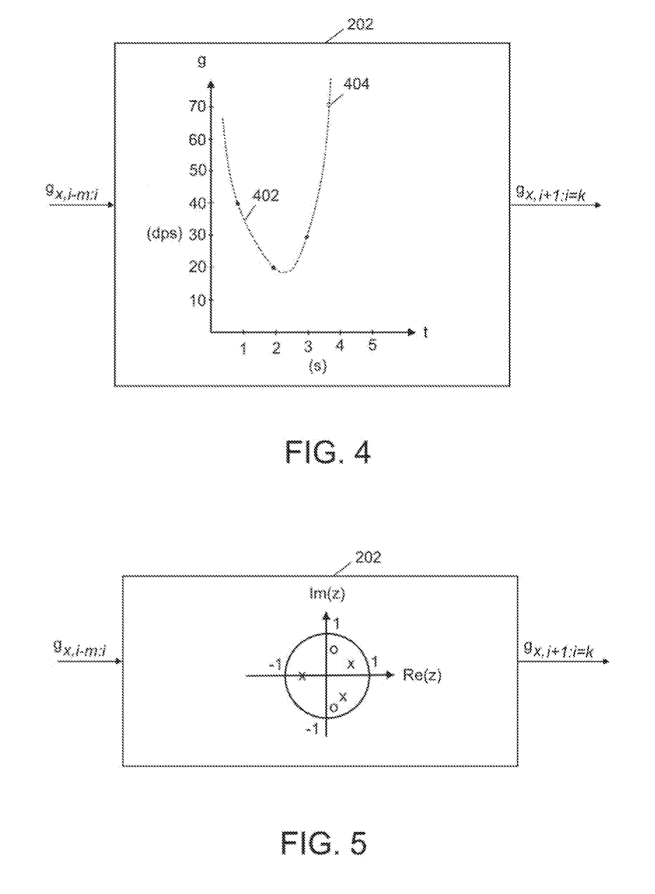

In another aspect, data prediction block 202 may be configured to fit a nonlinear function to current and past sensor data. Again, the following discussion is in the context of gyroscope data in the body X axis alone, but the techniques may be extended to the other body axes and/or to other motion sensor data. A block diagram showing a nonlinear prediction is schematically depicted in FIG. 4. Again, data prediction block 202 receives input in the form of current and past gyroscope data g_{x,i-m:i} for the body X axis of device 100. Data prediction block 202 may fit nonlinear function 402 to the past data represented by solid dots to allow for prediction of future data 404.

In the example shown, three past and current gyroscope signals are again [40 20 30] in dps sampled at times [1 2 3] s. A nonlinear function taking the form of Equation 9, wherein g is gyroscope, t is time and aⱼ's are coefficients to be solved may be generated.

g=a₂t²+a₁t+a₀ (9)

A similar least squares algorithm may fit a nonlinear function using the same A X=B form, wherein A is a matrix, X and B are vectors and A and B are data inputs to solve for X resulting in Equation 10.

$$[ \begin{matrix}{t}_{1}^{2} & {t}_{1} & 1 \\ {t}_{2}^{2} & {t}_{2} & 1 \\ {t}_{3}^{2} & {t}_{3} & 1\end{matrix} ] [ \begin{matrix}{a}_{2} \\ {a}_{1} \\ {a}_{0}\end{matrix} ] = [ \begin{matrix}{g}_{1} \\ {g}_{2} \\ {g}_{3}\end{matrix} ] \qquad ( 10 )$$

Substituting the values from the example shown in FIG. 4 results in Equation 11.

$$[ \begin{matrix}1 & 1 & 1 \\ 4 & 2 & 1 \\ 9 & 3 & 1\end{matrix} ] [ \begin{matrix}{a}_{2} \\ {a}_{1} \\ {a}_{0}\end{matrix} ] = [ \begin{matrix}40 \\ 20 \\ 30\end{matrix} ] \qquad ( 11 )$$

Similarly, an estimate of X may be obtained by multiplying the pseudoinverse of A, A⁺, by B to provide the solution indicated by Equation 12.

$$X = {A}^{+} B = [ \begin{matrix}0.5 & - 1.0 & 0.5 \\ - 2.5 & 4.0 & - 1.5 \\ 3.0 & - 3.0 & 1.0\end{matrix} ] [ \begin{matrix}40 \\ 20 \\ 30\end{matrix} ] = [ \begin{matrix}15 \\ - 65 \\ 90\end{matrix} ] \qquad ( 12 )$$

Using the aⱼ solutions, the predicted gyroscope signal for the X axis at time 4 s 404 may be predicted to be 70 dps.

In another aspect, data prediction block 202 may be configured as a dynamic system to provide a frequency domain representation of a differential equation that has been fit to past and current data. Fitting a differential equation to past data may serve as a model of typical behavior of device 100. In some embodiments, the fitting process may employ system identification techniques as known in control theory, allowing the fitted differential equation to predict future signal outputs. A schematic representation of data prediction block 202 configured as a discrete dynamic system is shown in FIG. 5, depicted as a pole-zero plot in which the x's represent the system's poles and may be viewed as indicating how fast the system responds to inputs and in which the o's represent zeroes and may indicate overshoot characteristics of the system. As will be appreciated, the dynamic system may be discrete or continuous, may utilize single or multiple inputs and/or outputs representing the body axes and may be used in combination with other prediction techniques.

As one example of applying a dynamic system to predict motion sensor data, five X axis gyroscope signals [40 20 30 10 0] in dps may be taken at times [1 2 3 4 5] s. In this example, a dynamic system is fit to inputs of two past gyroscope values to output a prediction of the gyro at the current step using Equation 13, wherein gp is the predicted gyroscope signal, g is actual gyroscope data at time step index k, and aⱼ's are coefficients to be solved.

gpₖ=a₁gₖ₋₁a₂gₖ₋₂ (13)

Accordingly, data in this example may be used for fitting a dynamic system by assuming that two past gyroscope values lead to the current one. As such, the data may be split into groups of 3 consecutive values, such as g₁ and g₂ leading to g₃, g₂ and g₃ leading to g₄, and so on. A least squares technique may be applied using the form A X=B to generate Equation 14.

$$[ \begin{matrix}{g}_{1} & {g}_{2} \\ {g}_{2} & {g}_{3} \\ {g}_{3} & {g}_{4}\end{matrix} ] [ \begin{matrix}{a}_{2} \\ {a}_{1}\end{matrix} ] = [ \begin{matrix}{g}_{3} \\ {g}_{4} \\ {g}_{5}\end{matrix} ] \qquad ( 14 )$$

Substituting with the values from the example results in Equation 15.

$$[ \begin{matrix}40 & 20 \\ 20 & 30 \\ 30 & 10\end{matrix} ] [ \begin{matrix}{a}_{2} \\ {a}_{1}\end{matrix} ] = [ \begin{matrix}30 \\ 10 \\ 0\end{matrix} ] \qquad ( 15 )$$

Similarly, an estimate of X may be obtained by multiplying the pseudoinverse of A, A⁺, by B to provide the solution indicated by Equation 16.

$$X = {A}^{+} B = [ \begin{matrix}0.37 \\ 0.20\end{matrix} ] \qquad ( 16 )$$

Using the aⱼ solutions and Equation 12, the predicted gyroscope signal for the X axis at time 6 s may be predicted to be 3.7 dps. Subsequent predictions, for example g₇, may be obtained by using the predicted g₇ in the difference equation for gₖ, resulting in an iterative process as distinguished from the linear and nonlinear techniques discussed above.

The dynamic system derived in this example may be further characterized in the frequency domain. A Discrete Time Fourier Transform may be used to generate Equation 17, wherein negative indices become powers of shift operator z, G(z) represents a frequency characteristic of past gyroscope data, and Gp(z) represents a frequency characteristic of the predicted gyroscope data.

Gp(z)=a₁G(z)z⁻¹+a₂G(z)z⁻² (17)

Accordingly, the transfer function of the dynamic system may be represented as the ratio of the output to input as shown in Equation 18.

$$\frac{Gp ( z )}{G ( z )} = {a}_{1} {z}^{- 1} + {a}_{2} {z}^{- 2} = \frac{{a}_{1} z + {a}_{2}}{{z}^{2}} \qquad ( 18 )$$

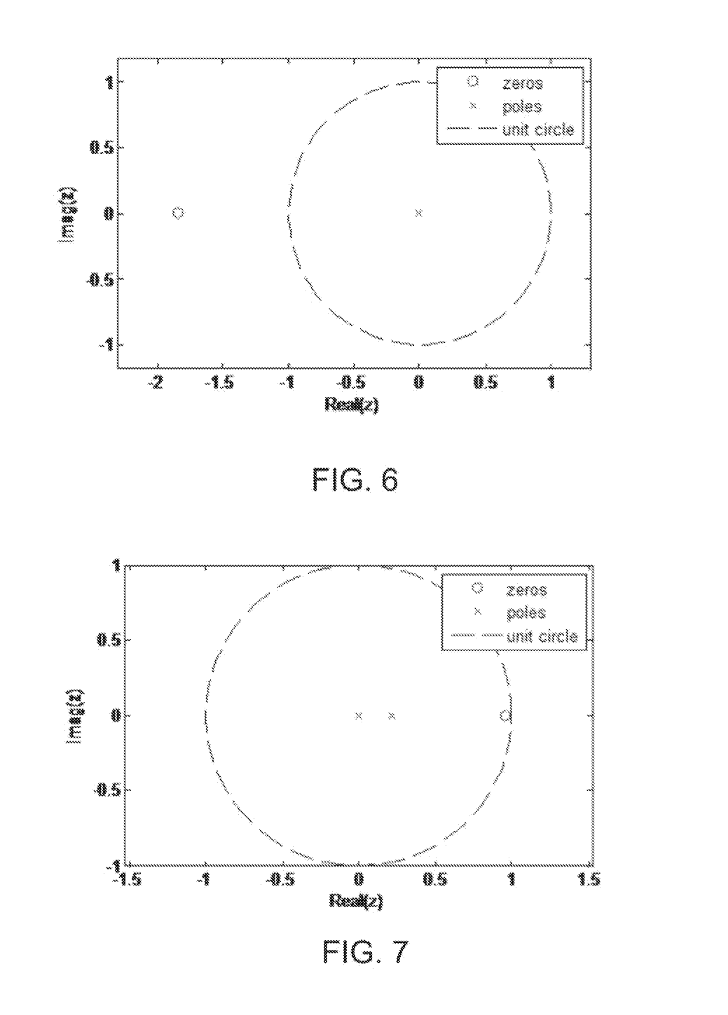

As will be appreciated, this transfer function may be seen to have one zero at the value of a₂/a₁, the root of the numerator polynomial, and two poles at 0 as shown in pole-zero diagram depicted in FIG. 6. Since the poles are within the unit circle, the system may be considered stable in that the output will not grow unbounded so long as the input is bounded, which may be a desirable characteristic for orientation prediction.

Further, in the above example, all the poles of the system lie at zero, indicating this dynamic system has finite impulse response (FIR). As an alternative, fitting the differential equation may take the form as expressed in Equation 19, wherein the b-coefficients are linked to the inputs (past actual gyroscope data) and the a-coefficients are linked to the outputs (past predicted gyroscope data).

gpₖ=b₁gₖ₋₂+b₂gₖ₋₂+a₁gₖ₋₁ (19)

Similarly, the transfer function of the dynamic system may be represented as the ratio of the output to input as shown in Equation 20.

$$\frac{Gp ( z )}{G ( z )} = \frac{{b}_{1} z + {b}_{2}}{{z}^{2} - {a}_{1} {z}^{2}} \qquad ( 20 )$$

For comparison, the same data used in the previous example may be used to obtain predicted gyroscope data. By casting the difference equation in the form A X=B to utilize a least squares technique, Equation 21 may be generated, wherein predicted gyroscope data was the same as actual gyroscope data such that gp₃=g₃, gp₄=g₄ and gp₅=g₅, for simplicity.

$$[ \begin{matrix}{g}_{1} & {g}_{2} & {gp}_{3} \\ {g}_{2} & {g}_{3} & {gp}_{4}\end{matrix} ] [ \begin{matrix}{b}_{2} \\ {b}_{a} \\ {a}_{1}\end{matrix} ] = [ \begin{matrix}{gp}_{4} \\ gp 5\end{matrix} ] \qquad ( 21 )$$

Substituting with the values from the example results in Equation 22.

$$[ \begin{matrix}40 & 20 & 30 \\ 20 & 30 & 10\end{matrix} ] [ \begin{matrix}{b}_{2} \\ {b}_{a} \\ {a}_{1}\end{matrix} ] = [ \begin{matrix}10 \\ 0\end{matrix} ] \qquad ( 22 )$$

Again, an estimate of X may be obtained by multiplying the pseudoinverse of A, A⁺, by B to provide the solution indicated by Equation 23.

$$X = {A}^{+} B = [ \begin{matrix}0.19 \\ - 0.20 \\ 0.21\end{matrix} ] \qquad ( 23 )$$

Thus, the pole-zero diagram depicted in FIG. 7 for this dynamic system has one non-zero pole at 0.21, and therefore may be seen to have an infinite impulse response (IIR). Correspondingly, all past data has an effect on the current prediction as compared to a FIR system in which only a few past samples, such as two in the previous example, have an effect on the current prediction. As a result, the effects of past data are perpetuated forward even when past data is outside the input window.

As will be appreciated, other training setups, such as those with different number of poles and zeroes, with complex pairs of poles and/or zeros, and/or relating not only past gyroscope x-axis to future predictions, but also interlinking the orthogonal axes, may be used according to the techniques of this disclosure.

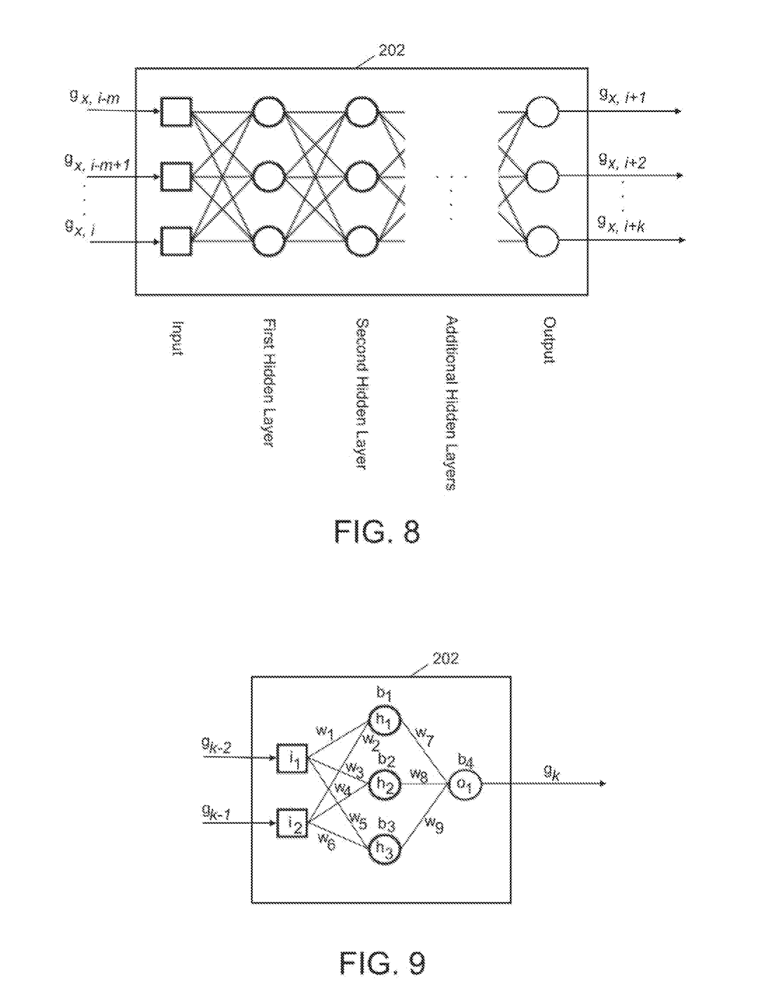

In yet another aspect, data prediction block 202 may be configured as an artificial neural network (ANN). As shown in FIG. 8, inputs to data prediction block 202 may be previous gyroscope data, such as data for the X body axis from m previous time steps leading to current time step i. Data prediction block 202 may output predicted signals at immediate next time step i+1 up to k steps into the future i+k. As known to those of skill in the art, the ANN implemented by data prediction block 202 may include one or more hidden layers of neurons, such that each previous layer is connected to the subsequent layer by varying links as established by training device 100. Although the hidden layers are depicted as having the same number of neurons as the inputs and outputs, each hidden layer may have any number of neurons depending upon the implementation. As with the other prediction techniques described above, an ANN may be trained on a gyroscope signal alone or in conjunction with other sensors, such as an accelerometer and/or a magnetometer.

To help illustrate aspects of an ANN implementation, use of a suitably configured data prediction block 202 to predict motion sensor data is described in the following example. Again, past and current motion sensor data may be represented by five X axis gyroscope signals [40 20 30 10 0] in dps, taken at times [1 2 3 4 5] s. As described above with regard to the dynamic system, the data may be split into groups of 3 consecutive values, such as g₁ and g₂ leading to g₃ and g₂ and g₃ leading to g₄ for example. An input layer including neurons i₁ and i₂ receives two gyroscope samples gₖ₋₂ and gₖ₋₁ preceding a predicted gyroscope sample gₖ. As shown, the input layer is connected to a hidden layer of neurons h₁-h₃, each having a bias and respective weights applied to the inputs. For example, neuron h₁ has a bias of b₁ and receives the input from neuron i₁ weighted by w₁ and the input from neuron i₂ weighted by w₂. Similarly, the neuron h₂ has a bias of b₂ and weights inputs by w₃ and w₄ while neuron h₃ has a bias of b₃ and weights inputs by w₅ and w₆, respectively. An output layer of neuron o₁ receives the outputs from the hidden layer neurons h₁-h₃, has a bias of b₄ and weights the inputs by w₇, w₈ and w₉, respectively. In this embodiment, each neuron applies an activation function with respect to its bias. For example, each neuron may multiply the inputs by the corresponding weights and compares them to its bias, such that if the sum is greater than the bias, a logical value of 1 is output and otherwise a logical value of 0 is output. For example, the function performed at neuron h₁ may be expressed by Equation 24.

h₁=(w₁gₖ₋₁+w₂gₖ₋₂)>b₁ (24)

Thus, the ANN represented by data prediction block 202 may be represented as one condensed expression, Expression 25.

gₖ=o₁=[w₇(w₁gₖ₋₁+w₂gₖ₋₂>b₁)+w₈(w₃gₖ₋₁+w₄gₖ₋₂>b₂)+w₉(w₅gₖ₋₁+w₆gₖ₋₂>b₃)]>b₄ (25)

As will be appreciated, the weights and biases in Equation 25 may be trained using iterative nonlinear optimization approaches such as genetic algorithms, a Broyden-Fletcher-Goldfarb-Shanno algorithm, or others to adjust the weights w₁-w₉ and biases b₁-b₄ to minimize the differences between a predicted gyroscope sample and the actual gyroscope sample obtained at the corresponding time. As an illustration, weights w₁-w₉ [5 18 −23 9 3 −13 −4 3 36] and biases b₁-b₄ [28 −13 30 7] may be applied to gyroscope data g₁-g₂ [40 20] to achieve an output of 0. In the above embodiment, it may be seen that Equation 25 outputs only 0 or 1. To provide additional refinement, the if-statements may be replaced with sigmoid functions to output continuous values between 0 and 1. For example, in one embodiment, using sigmoid functions with the above parameters may provide an output of 0.517. As desired, the value of neuron o₁ may be further scaled by another trained weight, w₁₀.

Accordingly, data prediction block 202 may be implemented using any desired combination of the above techniques or in any other suitable manner. The predicted motion sensor data may then be fed to sensor fusion block 204 as indicated by FIG. 2. As one of skill in the art will appreciate, a number of techniques may be employed to combine predicted motion sensor data with current and/or past determinations of device 100 orientation to provide a predicted orientation of device 100. To help illustrate this aspect, one embodiment of sensor fusion block 204 may be configured to receive as inputs a quaternion representing an orientation of device 100 as currently determined using actual motion sensor data, qᵢ, and a predicted gyroscope sample for the next time step, gᵢ₊₁, output from data prediction block 202 as indicated in FIG. 2. Correspondingly, the predicted orientation of device 100 for the next time step, qᵢ₊₁, may be obtained by integrating the predicted gyroscope data using Equation 26, wherein matrix operator L converts the quaternion into a 4×4 matrix required for quaternion multiplication, [0 gᵢ] converts the gyroscope data into a quaternion vector with the first element being zero, and Δt is the sampling period between each time step.

$${q}_{i + 1} = {q}_{i} + L ( {q}_{i} ) [ \begin{matrix}0 \\ {g}_{i + 1}\end{matrix} ] \frac{Δ t}{2} \qquad ( 26 )$$

Since Equation 26 returns an approximated quaternion, the output may be normalized using Equation 27 to scale the predicted quaternion to unity.

$${q}_{i + 1} = \frac{{q}_{i + 1}}{‖ {q}_{i + 1} ‖} \qquad ( 27 )$$

Subsequent future orientations of device 100 may be determined by iteratively combining a quaternion representing a predicted orientation at a given time step with motion sensor data predicted for the next time step.

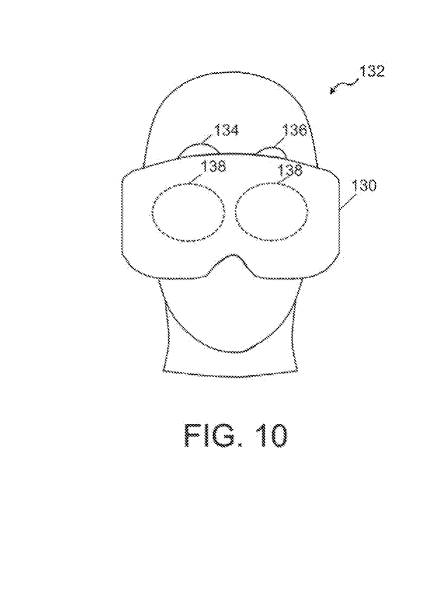

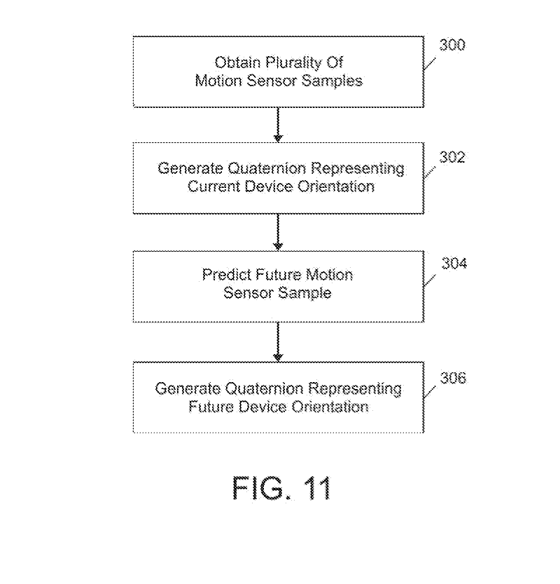

As noted above, device 100 may be implemented as a head mounted display 130 to be worn by a user 132 as schematically shown in FIG. 10. Any desired combination of motion sensors, including gyroscopes, accelerometers and/or magnetometers for example, in the form of external sensor 108 and/or internal sensor 116 may be integrated into tracking unit 134. When an internal sensor is employed, tracking unit 134 may also include MPU 102. In turn, host processor 104 and host memory 106 may be implemented in computational unit 136, although they may be integrated with tracking unit 134 in other embodiments. Tracking unit 134 may be configured so that a determined orientation using the motion sensors aligns with the user's eyes to provide an indication of where the user is looking in three dimensional space. As a result, image generator 120 (not shown in FIG. 11) may render an appropriate scene of the virtual environment corresponding to the determined orientation of the user's gaze. Display 122 may take the form of stereoscopic screens 138 positioned in front of each eye of the user. Using techniques known in the art, depth perception may be simulated by providing slightly adjusted images to each eye. In other applications, display 122 may be implemented externally using any combination of static or mobile visual monitors, projection screens or similar equipment.

To help illustrate aspects of this disclosure, FIG. 12 is a flow chart showing a suitable process for predicting a future orientation of device 100. Beginning in 300, a plurality of motion sensor samples may be obtained for device 100 up to a current time, such as from external sensor 108 and/or internal sensor 116. In 302, a quaternion representing a current orientation of device 100 may be generated using any available processing resources. In one embodiment, MPU 102 containing sensor processor 112 may be configured to determine the current orientation of device 100. Next, a future motion sensor sample may be predicted using data prediction block 202 in 304 using any of the techniques described above, a combination thereof, or the equivalent. The motion sensor sample may be predicted, based at least in part, on the plurality of motion samples obtained up to the current time. In turn, sensor fusion block 204 may generate a quaternion in 306 that represents a predicted future orientation of the device by fusing the predicted future motion sensor sample from data prediction block 202 with the currently determined orientation quaternion.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. A method for predicting a future orientation of a device configured to be moved by a user, comprising:
obtaining a plurality of motion sensor samples for the device up to a current time;
generating a quaternion representing a current orientation of the device;
predicting a future motion sensor sample, based at least in part, on the plurality of motion samples obtained up to the current time; and
generating a quaternion representing a predicted future orientation of the device by fusing the predicted future motion sensor sample with the current orientation quaternion.

2. The method of claim 1, further comprising predicting a plurality of predicted future motion sensor samples, wherein each motion sensor sample represents a successive future time and generating a plurality of quaternions representing predicted future orientations of the device, wherein each generated quaternion is derived by fusing one of the plurality of motion sensor samples with a preceding orientation quaternion.

3. The method of claim 1, wherein predicting a future motion sensor sample comprises predicting data from at least one of the group consisting of a gyroscope, an accelerometer and a magnetometer.

4. The method of claim 1, wherein predicting a future motion sensor sample comprises deriving a linear function from the plurality of motion sensor samples.

5. The method of claim 1, wherein predicting a future motion sensor sample comprises deriving a nonlinear function from the plurality of motion sensor samples.

6. The method of claim 1, wherein predicting a future motion sensor sample comprises providing a frequency domain representation of a differential equation corresponding to typical motion of the device receiving as inputs the plurality of motion sensor samples.

7. The method of claim 6, further comprising training the differential equation.

8. The method of claim 1, wherein predicting a future motion sensor sample comprises providing an artificial neural network representing typical motion of the device receiving as inputs the plurality of motion sensor samples.

9. The method of claim 8, further comprising training the artificial neural network.

10. The method of claim 1, wherein predicting a future motion sensor sample comprises combining a plurality of predictions obtained from the group consisting of deriving a linear function from the plurality of motion sensor samples, deriving a nonlinear function from the plurality of motion sensor samples, providing a frequency domain representation of a differential equation corresponding to typical motion of the device receiving as inputs the plurality of motion sensor samples and providing an artificial neural network representing typical motion of the device receiving as inputs the plurality of motion sensor samples.

11. The method of claim 1, wherein generating the quaternion representing a predicted future orientation of the device comprises integrating the predicted future motion sensor sample with the current orientation quaternion.

12. The method of claim 1, further comprising generating a graphical representation of a virtual environment using the predicted future orientation quaternion.

13. The method of claim 12, wherein the device is configured to track the motion of the user's head.

14. A system for predicting orientation, comprising:
a device configured to be moved by a user outputting motion sensor data;
a data prediction block configured to receive a plurality of samples of the motion sensor data up to a current time and output a predicted future motion sensor sample;
a quaternion generator configured to output a quaternion representing a current orientation of the device; and
a sensor fusion block configured to generate a quaternion representing a predicted future orientation of the device by combining the predicted future motion sensor sample with a preceding orientation quaternion.

15. The system of claim 14, wherein the data prediction block is configured to output a plurality of predicted future motion sensor samples, wherein each motion sensor sample represents a successive future time and wherein the sensor fusion block is configured to generate a plurality of quaternions representing predicted future orientations of the device each derived by combining one of the plurality of motion sensor samples with a preceding orientation quaternion.

16. The system of claim 14, wherein the data prediction block is configured to predict data from at least one of the group consisting of a gyroscope, an accelerometer and a magnetometer.

17. The system of claim 14, wherein the data prediction block is configured to output the predicted future motion sensor sample by deriving a linear function from the plurality of motion sensor samples.

18. The system of claim 14, wherein the data prediction block is configured to output the predicted future motion sensor sample by deriving a nonlinear function from the plurality of motion sensor samples.

19. The system of claim 14, wherein the data prediction block comprises a frequency domain representation of a differential equation corresponding to typical motion of the device receiving as inputs the plurality of motion sensor samples.

20. The system of claim 14, wherein the data prediction block comprises an artificial neural network representing typical motion of the device receiving as inputs the plurality of motion sensor samples.

21. The system of claim 14, wherein the sensor fusion block is configured to generate the quaternion representing a predicted future orientation of the device by integrating the predicted future motion sensor sample with the current orientation quaternion.

22. The system of claim 14, further comprising an image generator configured to render a graphical representation of a virtual environment using the predicted future orientation quaternion.

23. The system of claim 22, wherein the device is configured to track the motion of the user's head.

24. The system of claim 23, further comprising a display configured to output the rendered graphical representation.
